(19) United States
(12) Patent Application Publication
(10) Pub. No.: US 2026/0018370 A1
(43) Pub. Date: Jan. 15, 2026

(54) APPARATUS FOR DETECTING ELECTRON, METHOD FOR DETECTING ELECTRON SIGNAL, AND ELECTRON MICROSCOPE

(71) Applicant: DONGFANG JINGYUAN ELECTRON CO., LTD., Beijing (CN)

(72) Inventor: Qinglang Meng, Beijing (CN)

(21) Appl. No.: 19/334,340

(22) Filed: Sep. 19, 2025

(30) Foreign Application Priority Data
Sep. 23, 2024 (CN) 202411331728.2

(51) Int. Cl. H01J 37/147; H01J 37/10

(52) U.S. Cl. CPC H01J 37/1471; H01J 37/10

(57) ABSTRACT

The present application discloses an apparatus for detecting an electron, a method for detecting an electron signal, and an electron microscope. The apparatus for detecting an electron includes a first centering assembly, a detector assembly, a second centering assembly, an objective lens, and a sample stage for placing a test sample. The first centering assembly is configured to control an electron beam to be deflected, so that the deflected electron beam deviates by a first distance from a column axis of the electron microscope; the second centering assembly is configured to control the deflected electron beam to be re-deflected, so that a distance between the electron beam and the column axis is less than a preset distance; the objective lens is configured to converge the electron beam and act on the test sample, so as to generate a return electron signal.

### CROSS-REFERENCE TO RELATED APPLICATIONS

This application claims priority to Chinese Patent Application No. 202411331728.2, titled “APPARATUS FOR DETECTING ELECTRON, METHOD FOR DETECTING ELECTRON SIGNAL, AND ELECTRON MICROSCOPE” and filed on Sep. 23, 2024, which is hereby incorporated by reference in its entirety.

### TECHNICAL FIELD

The present application relates to the technical field of electron microscopes, and particularly, to an apparatus for detecting an electron, a method for detecting an electron signal, and an electron microscope.

### BACKGROUND

In recent years, electron microscopes have been widely used in the semiconductor industry. The operating principle of the electron microscopes is: bombarding the surface of an object to be detected using a charged particle beam, and detecting an electron signal generated in the bombarded area by a detector to acquire various physical and chemical information of the test sample, such as morphology, composition, feature distribution, and the like.

Detectors may be divided into on-axis detectors and off-axis detectors based on different placement positions. In the off-axis detection method, a high-voltage electric field is applied to the off-axis detectors, and the electron signal generated by the test sample is collected by the detectors under the action of the high-voltage electric field, but the high-voltage electric field may also affect the path along which the electron beam moves to the test sample, thereby reducing the quality of a main electron beam.

Further, the quality of the main electron beam also determines the imaging quality of the electron microscopes, and the reduction in the quality of the main electron beam means the reduction in the imaging quality of the electron microscopes.

### SUMMARY

Embodiments of the present application provide an apparatus for detecting an electron, a method for detecting an electron signal, and an electron microscope, so that applying a high-voltage electric field to an off-axis detector can be avoided, and the problem that reduced quality of a main electron beam and reduced imaging quality are caused by applying the high-voltage electric field to the off-axis detector can be solved.

In one aspect, an embodiment of present application provides an apparatus for detecting an electron, which is applied to an electron microscope, wherein the apparatus for detecting the electron comprises a first centering assembly, a detector assembly, a second centering assembly, an objective lens, and a sample stage for placing a test sample;
the first centering assembly is configured to control an electron beam to be deflected so that the deflected electron beam deviates by a first distance from a column axis of the electron microscope;
the second centering assembly is configured to control the deflected electron beam to be re-deflected, so that a distance between the re-deflected electron beam and the column axis is less than a preset distance;
the objective lens is configured to converge the electron beam deflected by the second centering assembly, so that the converged electron beam acts on the test sample, and the test sample generates a return electron signal under an action of the electron beam, wherein an energy of the return electron signal is less than an energy of the electron beam;
the second centering assembly is further configured to control the return electron signal to be deflected, so that the deflected return electron signal deviates by a second distance from the column axis; and
the detector assembly deviates from the column axis to avoid the electron beam passing through the first centering assembly, wherein the detector assembly is configured to receive the deflected return electron signal.

In some embodiments, the first centering assembly, the detector assembly, the second centering assembly, the objective lens, and the sample stage are sequentially provided along the column axis; the first centering assembly comprises a first centering component and a second centering component that are sequentially provided along a direction of the column axis;
the first centering component is configured to control the electron beam to be deflected by a first preset angle along a direction away from the column axis; and
the second centering component is configured to control the electron beam deflected by the first preset angle to be re-deflected along a direction approaching the column axis, so that the re-deflected electron beam deviates by the first distance from the column axis of the electron microscope.

In some embodiments, the second centering assembly comprises a third centering component and a fourth centering component that are sequentially provided along the direction of the column axis;
the third centering component is configured to control the electron beam to be deflected by a second preset angle along the direction approaching the column axis; and
the fourth centering component is configured to control the electron beam deflected by the second preset angle to be re-deflected along the direction away from the column axis, so that a distance between the re-deflected electron beam and the column axis is less than the preset distance.

In some embodiments, each of the first centering component, the second centering component, the third centering component, and the fourth centering component comprises: a first conductive plate and a second conductive plate.

In some embodiments, each of of the first centering component, the second centering component, the third centering component, and the fourth centering component comprises a conductive coil.

In some embodiments, the detector assembly comprises at least one detector comprising a receiving surface for receiving the return electron signal.

In some embodiments, the receiving surface comprises a plurality of sub-receiving surfaces sequentially arranged along a radial direction of a column, and each of the sub-receiving surfaces is configured to receive the return electron signal with a corresponding energy.

In another aspect, an embodiment of the present application provides a method for detecting an electron signal, which is applied to the apparatus for detecting the electron in the above embodiment. The method for detecting an electron signal comprising:
applying a first electrical signal to the first centering assembly, and controlling, through the first centering assembly applied by the first electrical signal, the electron beam to be deflected, so that the deflected electron beam deviates by the first distance from the column axis of the electron microscope;
applying a second electrical signal to the second centering assembly, and controlling, through the second centering assembly applied by the second electrical signal, the deflected electron beam to be re-deflected, so that the distance between the re-deflected electron beam and the column axis is less than the preset distance;
converging, by an objective lens, the electron beam deflected by the second centering assembly to which the second electrical signal is applied, so that the converged electron beam acts on the test sample placed on the sample stage, and the test sample generates the return electron signal, where the energy of the return electron signal is less than the energy of the electron beam;
controlling, by the second centering assembly to which the second electrical signal is applied, the return electron signal to be deflected, so that the deflected return electron signal deviates by the second distance from the column axis; and
receiving the deflected return electron signal by the detector assembly.

In some embodiments, the detector assembly comprises the at least one detector comprising the receiving surface, the receiving surface comprises the plurality of sub-receiving surfaces sequentially arranged along the radial direction of the column; and
the receiving the deflected return electron signal by the detector assembly comprises:
receiving, by each of the sub-receiving surfaces of the detector of the detector assembly, the return electron signal with the corresponding energy.

In yet another aspect, an embodiment of the present application provides an electron microscope, comprising the apparatus for detecting the electron in the above embodiments.

In the apparatus for detecting an electron according to the embodiments of the present application, the electron beam is controlled by the first centering assembly to be deflected, so that the deflected electron beam deviates by the first distance from the column axis of the electron microscope; the deflected electron beam is controlled by the second centering assembly to be re-deflected, so that the distance between the re-deflected electron beam and the column axis is less than the preset distance; the electron beam deflected through the second centering assembly is converged by the objective lens, so that the converged electron beam acts on the test sample, and the test sample generates the return electron signal under the action of the electron beam, where the energy of the return electron signal is less than the energy of the electron beam; and the return electron signal is controlled by the second centering assembly to be deflected, so that the deflected return electron signal deviates by the second distance from the column axis, where the detector assembly deviates from the column axis and is configured to avoid the electron beam deflected through the first centering assembly and receive the deflected return electron signal. Therefore, it may be seen that in the embodiments of the present application, in the path along which the electron beam moves to the test sample, the electron beam may be deflected along different directions by the first centering assembly and the second centering assembly, so that the electron beam can act on the test sample along the emission direction of the electron beam, and the return electron signal detected by the detector is the effective signal. In the moving path of the return electron beam, the return electron signal may be deflected by the second centering assembly. Since the energy of the return electron signal is less than the energy of the electron beam, the deflection angles of the return electron signal and the electron beam in the second centering assembly are different from each other, and the less the energy of the electron signal is, the greater the deflection angle is. Therefore, the detector can avoid the electron beam and detect the return electron signal, and the return electron signal may be detected without applying any voltage to the detector, thereby avoiding the effect of the high-voltage electric field in the moving path of the electron beam and improving the quality of the electron beam.

### BRIEF DESCRIPTION OF THE DRAWINGS

In order to illustrate technical solutions of embodiments of the present application more clearly, the drawings required for the embodiments of the present application will be briefly described. For those skilled in the art, other drawings can also be obtained from these drawings without any inventive effort.

FIG. 1 is a schematic structural view of an exemplary electron microscope;

FIG. 2 is a schematic structural view of an apparatus for detecting an electron according to an embodiment of the present application;

FIG. 3 is a schematic structural view of a first centering assembly according to an embodiment of the present application;

FIG. 4 is a schematic structural view of a second centering assembly according to an embodiment of the present application;

FIG. 5 is a schematic structural view of a detector according to an embodiment of the present application;

FIG. 6 is a schematic flowchart of a method for detecting an electron signal according to an embodiment of the present application; and

FIG. 7 is a schematic structural view of an electron microscope according to an embodiment of the present application.

### DETAILED DESCRIPTION

Features and exemplary embodiments of various aspects of the present application will be described in detail below. In order to make the objects, technical solutions and advantages of the present application clearer, the present application is further described in detail below with reference to the drawings and specific embodiments. It should be understood that the specific embodiments described herein are merely intended to explain the present application, rather than to limit the present application. For those skilled in the art, the present application can be implemented without some of these specific details. The following description of the embodiments is only to provide a better understanding of the present application by illustrating examples of the present application.

It should be noted that, in the present disclosure, the relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device including a series of elements includes not only those elements, but also other elements that are not explicitly listed or elements inherent to such a process, method, article or device. Without more constraints, the elements following an expression “comprise/include . . . ” do not exclude the existence of additional identical elements in the process, method, article or device that includes the elements.

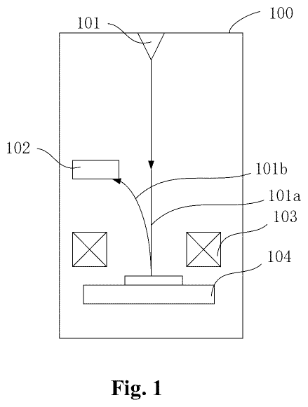

In recent years, electron microscopes have been widely used in the semiconductor industry. The surface of an object to be detected is bombarded using a charged particle beam, and an electron signal generated in the bombarded area is detected by a detector to acquire various physical and chemical information of the test sample, such as morphology, composition, feature distribution, and the like. FIG. 1 is an exemplary electron microscope 100. As shown in FIG. 1, the electron microscope 100 includes the electron beam emission source 101, the detector 102, the objective lens 103, and the sample stage 104. Under a condition that the electron microscope 100 is in operation, the high-voltage is applied to the detector 102. After the high-voltage is applied to the detector 102, the electron beam emission source 101 emits the electron beam 101a to cause the electron beam 101a to act on the test sample placed on the sample stage along the emission direction of the electron beam 101a and form the beam spot on the test sample. The test sample generates the return electron signal 101b under the action of the electron beam 101a. The return electron signal 101b is detected by the detector under the action of the high-voltage electric field.

When using the electron microscope, the applicant has found that although the high-voltage applied to the detector enables the detector to detect the return electron signal, the high-voltage applied to the detector may also affect the emitted electron beam, so that the quality of the electron beam is reduced, thereby reducing the quality of the beam spot and the imaging quality.

In order to solve at least one of the problems in the related art, embodiments of the present application provide an apparatus for detecting an electron. The apparatus for detecting an electron according to the embodiments of the present application is applicable to the electron microscope.

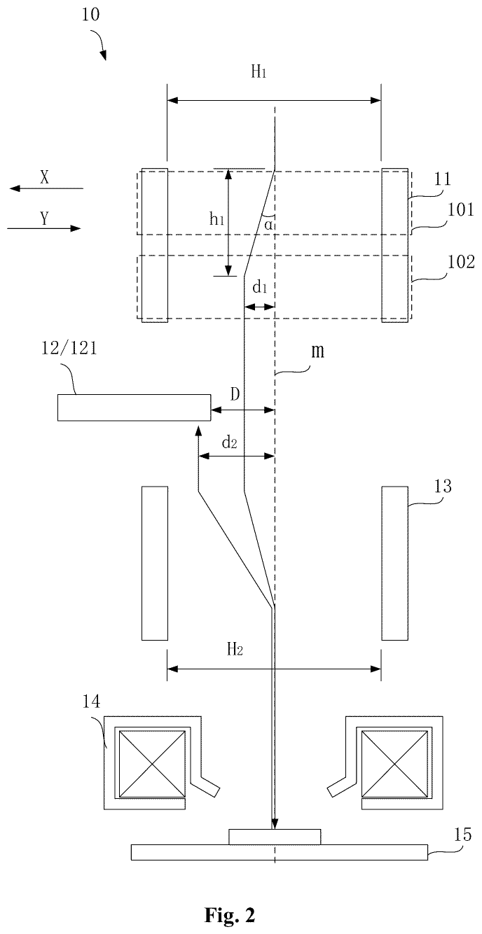

FIG. 2 is a schematic structural view of an apparatus for detecting an electron according to an embodiment of the present application.

Referring to FIG. 2, the apparatus 10 for detecting an electron according to the embodiments of the present application may include the first centering assembly 11, the detector assembly 12, the second centering assembly 13, the objective lens 14, and the sample stage 15 for placing the test sample. The first centering assembly 11, the detector assembly 12, the second centering assembly 13, the objective lens 14, and the sample stage 15 are sequentially provided along the column axis.

The first centering assembly 11 may be configured to control the electron beam to be deflected, so that the deflected electron beam deviates by the first distance d₁ from the column axis m of the electron microscope.

The second centering assembly 13 may be configured to control the deflected electron beam to be re-deflected, so that the distance between the re-deflected electron beam and the column axis m is less than the preset distance.

The objective lens 14 may be configured to converge the electron beam deflected by the second centering assembly 13, so that the converged electron beam acts on the test sample, and the test sample generates the return electron signal under the action of the electron beam. The energy of the return electron signal is less than the energy of the electron beam.

The second centering assembly 13 may be further configured to control the return electron signal to be deflected, so that the deflected return electron signal deviates by the second distance d₂ from the column axis m. The electrical signal is applied to the second centering assembly 13. Under the action of the electrical signal, the moving direction of the return electron signal is deflected.

The detector assembly 14 deviates by the column axis m to avoid the electron beam passing through the first centering assembly 11. The detector assembly 14 may be configured to receive the deflected return electron signal.

Specifically, the first centering assembly 11 may be located in the column of the electron microscope. For example, the first centering assembly 11 may be fixedly provided on the sidewall of the column of the electron microscope. The first centering assembly 11 is symmetrically distributed with respect to the column axis m. The electrical signal is applied to the first centering assembly 11, and the electron beam may be controlled through the first centering assembly 11 applied by the electrical signal to be deflected along the direction away from the column axis m. The moving direction of the deflected electron beam is parallel to the column axis m and deviates by the first distance d₁ from the column axis m of the electron microscope.

The second centering assembly 13 may be located in the column of the electron microscope. For example, the second centering assembly 13 may be fixedly provided on the sidewall of the column of the electron microscope. The second centering assembly 13 is symmetrically distributed with respect to the column axis m. The electrical signal is applied to the second centering assembly 13, and the electron beam may be controlled through the second centering assembly 13 applied by the electrical signal to be deflected along the direction approaching the column axis m, so that the distance between the deflected electron beam and the column axis m is less than the preset distance.

In some examples, the preset distance may be set based on the usage scenario. In the present application, the apparatus for detecting an electron is applied to the electron microscope. In the usage scenario of the electron microscope, the preset distance that may be set includes, but is not limited to, 0, 10 μm, 30 μm, 50 μm, 70 μm, 100 μm, 150 μm, 200 μm, 250 μm, and the like. It should be noted that under a condition that the preset distance is 0, it means that the deflected electron beam coincides with the column axis m.

Controlling the distance between the deflected electron beam and the column axis m to be within the preset distance ensures the quality of the beam spot formed when the electron beam acts on the test sample and avoids the reduction in the quality of the beam spot.

The objective lens 14 is located in the column of the electron microscope. The objective lens 14 may be an objective lens, such as an immersion objective lens, a non-immersion objective lens, a semi-immersion objective lens, or an electromagnetic compound objective lens. The electron beam deflected by the second centering assembly 13 may be focused onto the test sample by the objective lens 14.

The sample stage 15 is located outside the column of the electron microscope. The deceleration voltage may be applied to the sample stage. The direction of the deceleration voltage is opposite to the direction of the voltage of the electron beam emitted by the electron beam emission source, thereby decelerating the electron beam acting on the test sample to prevent the energy of the electron beam from being too high and causing damage to the surface of the test sample.

The detector assembly 12 deviates by a certain distance from the column axis m to avoid the electron beam and receive the return electron signal. The detector assembly 12 may be located in the column of the electron microscope. For example, the detector assembly 12 may be fixedly provided on the sidewall of the column of the electron microscope.

The detector assembly 12 may include at least one detector 121. The detector 121 may be a detector such as a semiconductor detector, a microchannel plate detector, and a scintillation detector.

The test sample may be a semiconductor wafer, a mask, an integrated circuit board, and the like.

Under the action of the voltage of the electron beam and the deceleration voltage, the test sample generates a return electron signal such as a backscattered electron signal or a secondary electron signal. The energy of the return electron signal is less than the energy of the electron beam. The return electron signal passes through the second centering assembly 13 applied by the electrical signal, and the second centering assembly 13 applied by the electrical signal controls the return electron signal to be deflected along the direction away from the column axis m. Since the energy of the return electron signal is less than the energy of the electron beam, the deflection angle of the return electron signal is greater than the deflection angle of the electron beam, so that the detector assembly 12 may avoid the electron beam and receive the return electron signal.

In the embodiments of the present application, in the path along which the electron beam moves to the test sample, the electron beam may be deflected along different directions by the first centering assembly and the second centering assembly, so that the electron beam can act on the test sample along the emission direction of the electron beam, and the return electron signal detected by the detector is the effective signal. In the moving path of the return electron signal, the return electron signal may be deflected by the second centering assembly. Since the energy of the return electron signal is less than the energy of the electron beam, the deflection angles of the return electron signal and the electron beam in the second centering assembly are different from each other, and the less the energy of the electron signal is, the greater the deflection angle is. Therefore, the detector can avoid the electron beam and detect the return electron signal, and the return electron signal may be detected without applying any voltage to the detector, thereby avoiding the effect of the high-voltage electric field in the moving path of the electron beam and improving the quality of the electron beam.

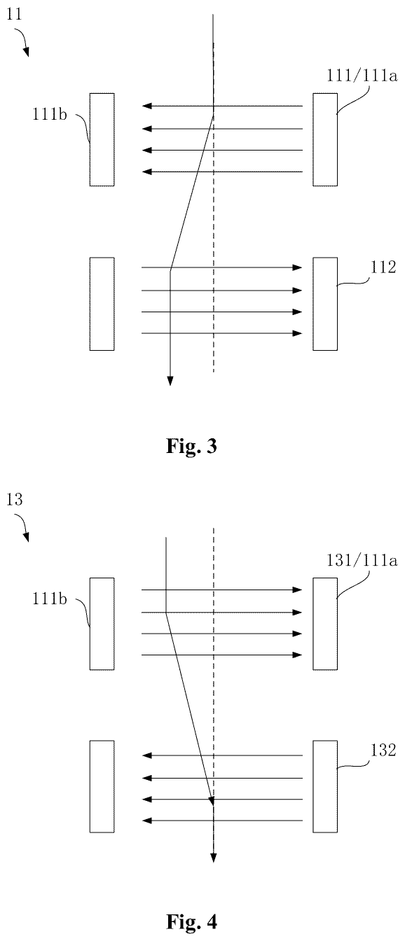

FIG. 3 is a schematic structural view of a first centering assembly according to an embodiment of the present application.

In some embodiments, optionally, the specific structure of the first centering assembly 11 shown in FIG. 2 of the present application may be referred to FIG. 3. As shown in FIG. 3, the first centering assembly 11 may include the first centering component 111 and the second centering component 112 sequentially provided along the direction of the column axis and along the direction approaching the sample stage 15. The first centering component 111 is configured to control the electron beam to be deflected by the first preset angle, so that the deflected electron beam is away from the column axis m. The second centering component 112 is configured to control the electron beam deflected by the first preset angle to be re-deflected, so that the re-deflected electron beam deviates by the first distance from the column axis m of the electron microscope and is parallel to the column axis m.

The first centering component 111 is configured to receive the electrical signal to control the electron beam to be deflected by the first preset angle along the direction away from the column axis m. The electrical signal may be a voltage signal or a current signal. For convenience of description, in the embodiments, the moving path of the electron beam in the first centering component is described by the example in which the electrical signal is the voltage signal. After the first centering component 111 receives the voltage signal, the electric field is formed in the first centering component 111. Under the action of the electric field, the electron beam gradually deviates from the column axis m along the direction of the electric field until the electron beam deviates by the first preset angle.

The first preset angle may be understood as the included angle between the moving direction of the deflected electron beam and the column axis m. The first preset angle is determined by the electrical signal applied to the first centering component 111. The greater the electrical signal is, the greater the first preset angle is.

The second centering component 112 is configured to receive an electrical signal. The magnitude of the electrical signal is equal to the magnitude of the electrical signal applied to the first centering component, and the direction of the electrical signal is opposite to the direction of the electrical signal applied to the first centering component, so as to control the electron beam deflected by the first preset angle to be deflected along the direction approaching the column axis m. The electrical signal may be a voltage signal or a current signal. For convenience of description, in the embodiments, the moving path of the electron beam in the second centering component is described by the example in which the electrical signal is the voltage signal. After the second centering component 112 receives the voltage signal, the electric field is formed in the first centering component 112. Under the action of the electric field, the electron beam gradually approaches the column axis m along the direction of the electric field until the electron beam is parallel to the column axis m.

The electrical signals along the opposite directions are applied to the first centering component 111 and the second centering component 112 respectively, so that the electron beam can move along the trajectory parallel to and at a certain distance from the column axis m. Therefore, the electron beam can act on the sample along the emission direction after passing through the second centering assembly 13.

FIG. 4 is a schematic structural view of a second centering assembly according to an embodiment of the present application.

In some embodiments, optionally, the specific structure of the second centering assembly 13 shown in FIG. 2 of the present application may be referred to FIG. 4. As shown in FIG. 4, the second centering assembly 13 may include the third centering component 131 and the fourth centering component 132 sequentially provided along the direction approaching the sample stage. The third centering component 131 is configured to control the electron beam to be deflected by the second preset angle, so that the deflected electron beam approaches the column axis m. The fourth centering component 132 is configured to control the electron beam deflected by the second preset angle to be re-deflected, so that the distance between the re-deflected electron beam and the column axis m is less than the preset distance.

The third centering component 131 is configured to receive an electrical signal. The magnitude of the electrical signal is equal to the magnitude of the electrical signal applied to the second centering component 112, and the direction of the electrical signal is the same as the direction of the electrical signal applied to the second centering component 112. Therefore, the electron beam deflected by the first centering assembly 11 is controlled to be deflected by the second preset angle along the direction approaching the column axis m. The electrical signal may be a voltage signal or a current signal. For convenience of description, in this embodiment, the moving path of the electron beam in the third centering component 131 is described by the example in which the electrical signal is the voltage signal. After the third centering component 131 receives the voltage signal, the electric field is formed in the third centering component 131. Under the action of the electric field, the electron beam gradually deflects to the column axis m along the direction of the electric field until the electron beam deviates by the second preset angle.

The second preset angle may be understood as the included angle between the moving direction of the electron beam deflected by the third centering component 131 and the moving direction (this direction is parallel to the column axis m) of the electron beam deflected by the first centering assembly 11. The second preset angle is determined by the electrical signal applied to the third centering component 131. The greater the electrical signal is, the greater the second preset angle is. Under a condition that the magnitude of the voltage applied to the third centering component 131 is equal to the magnitude of the voltage applied to the first centering assembly 11, the second preset angle is equal to the first preset angle.

The fourth centering component 132 is configured to receive an electrical signal. The magnitude of the electrical signal is equal to the magnitude of the electrical signal applied to the third centering component 131, and the direction of the electrical signal is opposite to the direction of the electrical signal applied to the third centering component 131, so as to control the electron beam deflected by the second preset angle to be deflected along the direction away from the column axis m. The electrical signal may be a voltage signal or a current signal. For convenience of description, in the embodiments, the moving path of the electron beam in the fourth centering component 132 is described by the example in which the electrical signal is the voltage signal. After the fourth centering component 132 receives the voltage signal, the electric field is formed in the fourth centering component 132. Under the action of the electric field, the electron beam deflected by the second preset angle no longer continues to move along the direction of the second preset angle, but gradually moves to the direction approaching the column axis m along the direction of the electric field until the distance of the electron beam from the column axis m is less than the preset distance.

The electrical signals along the opposite directions are applied to the third centering component 131 and the fourth centering component 132 respectively, so that the trajectory motion of the electron beam parallel to and at a certain distance from the column axis m is deflected to coincide with the column. Therefore, the electron beam acts on the sample along the emission direction.

In some embodiments, optionally, each of the first centering component 111 and the second centering component 112 shown in FIG. 3 of the present application and the third centering component 131 and the fourth centering component 132 shown in FIG. 4 of the present application may include the first conductive plate 111a and the second conductive plate 111b.

The first conductive plate 111a may be configured to receive the voltage signal or be grounded.

Under a condition that the first conductive plate 111a receives the voltage signal, the second conductive plate 111b may be configured to receive a voltage signal different from the voltage signal or may be grounded. In this way, the voltage difference is formed between the first conductive plate 111a and the second conductive plate 111b to form the electric field.

Under a condition that the first conductive plate 111a is grounded, the second conductive plate 111b may be configured to receive the voltage signal. In this way, the voltage difference is formed between the first conductive plate 111a and the second conductive plate 111b to form the electric field.

The voltage is applied to the first conductive plate 111a and the second conductive plate 111b of the first centering component 111, so that the electric field is formed between the first conductive plate 111a and the second conductive plate 111b of the first centering component 111. Under the action of the electric field, the electron beam passing through the first centering component 111 is deflected by the first preset angle along the direction of the column axis m. The voltage is applied to the first conductive plate 111a and the second conductive plate 111b of the second centering component 112, so that the electric field is formed between the first conductive plate 111a and the second conductive plate 111b of the second centering component 112. Under the action of the electric field, the electron beam gradually approaches the column axis m along the direction of the electric field, until the electron beam is parallel to the column axis m.

The voltage is applied to the first conductive plate 111a and the second conductive plate 111b of the third centering component 131, so that the electric field is formed between the first conductive plate 111a and the second conductive plate 111b of the third centering component. Under the action of the electric field, the electron beam passing through the third centering component 131 is deflected by the second preset angle along the direction of the column axis m. The voltage is applied to the first conductive plate 111a and the second conductive plate 111b of the fourth centering component 132, so that the electric field is formed between the first conductive plate 111a and the second conductive plate 111b of the fourth centering component 132. The direction of the electric field is different from the direction of the electric field formed in the third centering component 131, so that the electron beam deflected by the second preset angle along the direction of the column axis m moves along the direction approaching the column axis m, until the distance of the electron beam from the column axis m is less than the preset distance. Therefore, under a condition that the electron beam is deviated by the preset distance from the column axis m, the electron beam acts on the test sample.

The corresponding voltage is applied to the first conductive plates 111a and the second conductive plates 111b of the first centering component 111 and the second centering component 112, respectively, so that the electron beam can move along the trajectory parallel to and at the certain distance from the column axis m; and the corresponding voltage is applied to the first conductive plates 111a and the second conductive plates 111b of the third centering component 131 and the fourth centering component 132, respectively, so that the trajectory motion of the electron beam parallel to and at the certain distance from the column axis m is deflected, thus the distance of the electron beam from the column axis m is within the preset distance range, and the electron beam acts on the sample within the preset distance range deviating from the column axis m.

In some embodiments, optionally, each of the first centering component 111 and the second centering component 112 shown in FIG. 3 of the present application and the third centering component 131 and the fourth centering component 132 shown in FIG. 4 of the present application may include the conductive coil.

The corresponding currents are applied to the conductive coils of the first centering component 111 and the second centering component 112, respectively, so that the electron beam can move along the trajectory parallel to and at the certain distance from the column axis m; and the corresponding currents are applied to the conductive coils of the third centering component 131 and the fourth centering component 132, respectively, so that the trajectory motion of the electron beam parallel to and at the certain distance from the column axis m is deflected, thus the distance of the electron beam from the column axis m is within the preset distance range, and the electron beam acts on the sample within the preset distance range deviating from the column axis m.

In some embodiments, optionally, the detector 121 shown in FIG. 2 of the present application may include the receiving surface located on a side of the detector close to the objective lens, and the receiving surface may be configured to receive the return electron signal.

Since the energy of the electron beam is different from the energy of the return electron signal, the deflection angles the electron beam and the return electron signal are different from each other, and the less the energy is, the greater the deflection angle is, therefore, the motion trajectory of the return electron signal is different from the motion trajectory of the electron beam. After the second centering assembly 13 controls the return electron signal to be deflected, the second distance d₂ of the deflected return electron signal from the column axis m is greater than the first distance d₁ of the deflected electron beam from the column axis m; and the distance D of the detector from the column axis m, the first distance d₁, and the second distance d₂ satisfy d₁<D<d₂, so that the detector 121 can collect the return electron signal by the receiving surface.

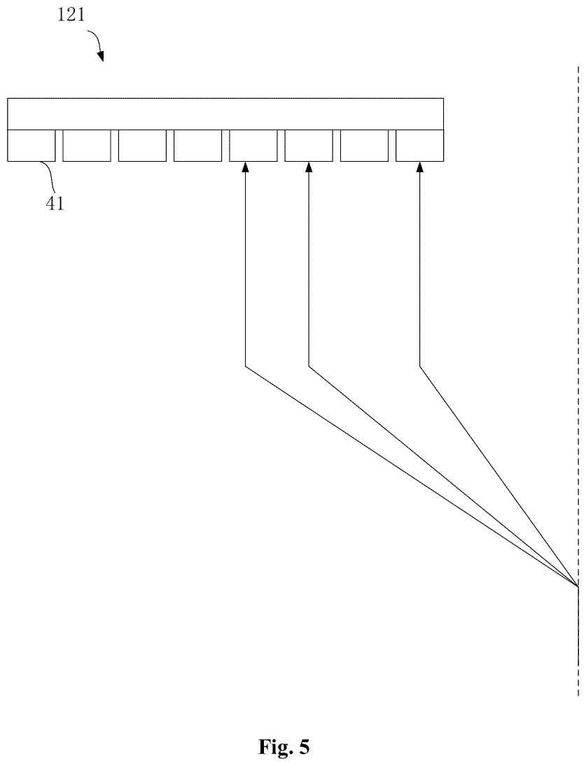

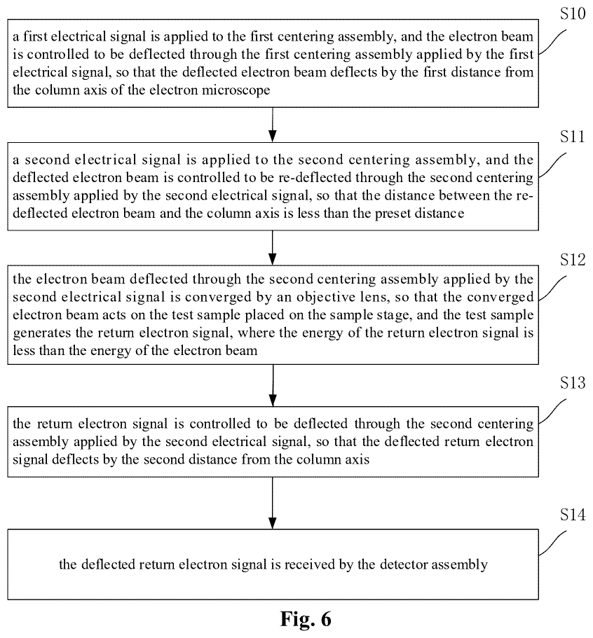

FIG. 5 is a schematic structural view of a detector according to an embodiment of the present application.

In some embodiments, optionally, the specific structure of the detector 121 shown in FIG. 2 of the present application may be referred to FIG. 5. As shown in FIG. 5, the detector 121 may include a plurality of sub-receiving surfaces 41 sequentially arranged along the radial direction of the column, and each of the sub-receiving surfaces 41 may be configured to receive the return electron signals with different energies.

The return electron signal is deflected after passing through the second centering component 13. The energies of the return electron signals are different from each other, and the deflection angles of the return electron signals are different from each other. After the return electron signal is deflected by the second centering assembly 13, under a condition that the return electron signal acts on the receiving surface of the detector, the distances of the return electron signals from the column axis m are different from each other. The greater the energy of the return electron signal is, the closer the return electron signal is to the column axis m, so that the return electron signals with different energies can be collected by the plurality of sub-receiving surfaces 41 sequentially arranged along the radial direction of the column, and the return electron signals with different energies can be separately imaged by the electron microscope.

In some embodiments, optionally, the apparatus for detecting an electron shown in FIG. 2 of the present application may further include the signal synthesizer (not shown in the drawing), and the number of the signal synthesizers may be set based on usage requirements. The signal synthesizer may be connected to the plurality of sub-receiving surfaces, synthesize the return electron signals detected by the plurality of sub-receiving surfaces, and output the electron signal synthesized image, thereby achieving mixed imaging.

In order to better understand the embodiments of the present application, the moving processes of the electron beam and the return electron signal in the apparatus for detecting an electron shown in FIG. 2 will be described below with reference to FIG. 2. In the apparatus for detecting an electron shown in FIG. 2, the electron beam reflection source is coaxial with the column of the electron microscope, the first centering assembly 11 is symmetrical with respect to the column axis m, the second centering assembly 13 is symmetrical with respect to the column axis m, and the detector assembly 12 includes the detector 121 located on a side of the column axis m. The distance of the first centering assembly 11 from the column axis m is

$$\frac{{H}_{1}}{2} ,$$

and the distance of the first centering assembly 12 from the column axis m is

$$\frac{{H}_{2}}{2} .$$

The energy of the electron beam emitted by the electron beam emission source may be E₁, for example, 10 keV, 12 keV, 14 keV, 16 keV, and the like. The energy may also be represented by the acceleration voltage U₁. For example, the energy of the electron beam is 10 keV, then the acceleration voltage corresponding to the electron beam is 10 kV. The deceleration energy applied to the sample stage may be E₂, and E₂<E₁. For example, E₂ may be 500 eV, 800 eV, 1 keV, 2 keV, 3 keV, and the like. The deceleration energy may also be represented by the deceleration voltage U₂. In this way, the generated equivalent voltage of the return electron signal is U₃, where U₃=U₁-U₂.

The voltage ΔV₁ is applied to the first centering assembly 11, the voltage ΔV₂ is applied to the second centering assembly 13, the effective length of the first centering assembly 11 is h₁, and the effective length of the second centering assembly 13 is h₂. The effective length may be understood as the length of the region in the first centering assembly or the second centering assembly where the electron beam is deflected.

The voltage ΔV₁ includes the sub-voltage ΔV′₁ and the sub-voltage ΔV″₁. The values of the sub-voltage ΔV′₁ and the sub-voltage ΔV″₁ are equal to the value of the voltage ΔV₁, and the direction of the sub-voltage ΔV′₁ is opposite to the direction of the sub-voltage ΔV″₁. The sub-voltage ΔV′₁ corresponds to the first field region 101 of the first centering assembly 11, and the sub-voltage ΔV″₁ corresponds to the second field region 102 of the first centering assembly 11. The first centering assembly 11 forms the sub-electric field ΔE′₁ and the sub-electric field ΔE″₁ under the action of the sub-voltage ΔV′₁ and the sub-voltage ΔV″₁, respectively, where the sub-electric field ΔE′₁ and the sub-electric field ΔE″₁ are perpendicular to the column axis m, and the directions of the sub-electric field ΔE′₁ and the sub-electric field ΔE″₁ are opposite to each other. Under a condition that the electron beam passes through the first centering assembly 11, the electron beam first passes through the region where the sub-electric field ΔE′₁ is located, and the sub-electric field ΔE′₁ enables the electron beam to deflect for the first time along the direction of the sub-electric field ΔE′₁, where the deflection angle is a. Under this condition, the deflection angle between the moving direction of the electron beam and the column axis m is a. The electron beam then passes through the region where the sub-electric field ΔE″₁ is located, and the sub-electric field ΔE″₁ enables the electron beam to deflect for the second time along the direction of the sub-electric field ΔE″₁, where the deflection angle is a. Under this condition, the moving direction of the electron beam is parallel to the column axis m and is at the first distance d1 from the column axis m of the electron microscope, where

$${d}_{1} = \frac{Δ {V}_{1} {h}_{1}^{2}}{4 {H}_{1} {U}_{1}} .$$

It should be noted that, in the example shown in FIG. 2 of the present application, the direction of the sub-electric field ΔE′₁ is the direction X, and the direction of the sub-electric field ΔE″₁ is the direction Y, which is not limited herein. The direction of the sub-electric field ΔE′₁ is determined by ΔV′₁ of the first field region 101 in the first centering assembly 11, and ΔV′₁ represents the potential difference formed by the first centering assembly in the first field region 101; the direction of the sub-electric field ΔE″₁ is determined by ΔV″₁ of the second field region 102 in the first centering assembly 11, and ΔV″₁ represents the potential difference formed by the first centering assembly in the second field region 102.

The voltage ΔV₂ includes the sub-voltage ΔV′₂ and the sub-voltage ΔV″₂. The values of the sub-voltage ΔV′₂ and the sub-voltage ΔV″₂ are equal to the value of the voltage ΔV₂, and the direction of the sub-voltage ΔV′₂ is opposite to the direction of the sub-voltage ΔV″₂. The sub-voltage 1V′₂ corresponds to the first field region of the second centering assembly 13, and the sub-voltage ΔV″₂ corresponds to the second field region of the second centering assembly 13. The second centering assembly 13 forms the sub-electric field ΔE′₂ and the sub-electric field ΔE″₂ under the action of the sub-voltage ΔV′₂ and the sub-voltage ΔV″₂, respectively, the sub-electric field ΔE′₂ and the sub-electric field ΔE″₂ are perpendicular to the column axis m and the directions of the sub-electric field ΔE′₂ and the sub-electric field ΔE″₂ are opposite to each other. Under a condition that the electron beam passes through the second centering assembly 13, the electron beam first passes through the region where the sub-electric field ΔE′₂ is located, and the sub-electric field ΔE′₂ enables the electron beam to deflect for the first time along the direction of the sub-electric field ΔE′₂, where the deflection angle is P; the electron beam then passes through the region where the sub-electric field ΔE″₂ is located, and the sub-electric field ΔE″₂ enables the electron beam to deflect for the second time along the direction of the sub-electric field ΔE″₂, where the deflection angle is P; under this condition, the moving direction of the electron beam coincides or substantially coincides with the column axis m. Whether the magnitude of the deflection angle α is equal to the magnitude of the deflection angle β depends on whether the voltage ΔV₂ is equal to the voltage ΔV₁, and the voltage ΔV₂ and the voltage ΔV₁ may be considered to be controlled. In the example, the example in which the voltage ΔV₂ is equal to the voltage ΔV₁ is given for description, so that the electron beam can hit the test sample along the column axis m, ensuring the quality of the beam spot of the electron beam on the test sample.

It should be noted that, in the example shown in FIG. 2 of the present application, the direction of the sub-electric field ΔE′₂ is the direction Y, and the direction of the sub-electric field ΔE″₂ is the direction X, which is not limited herein. The direction of the sub-electric field ΔE′₂ is determined by ΔV′₂ of the first field region in the second centering assembly 13, and ΔV′₂ represents the potential difference formed by the second centering assembly in the first field region; the direction of the sub-electric field ΔE″₂ is determined by ΔV″₂ of the second field region in the second centering assembly 13, and ΔV″₂ represents the potential difference formed by the second centering assembly in the second field region.

The electron beam converged by the objective lens 14 acts on the test sample placed on the sample stage 15, and the test sample generates the return electron signal, where the energy of the return electron signal is E₃.

Under a condition that the return electron signal passes through the second centering assembly 13, the return electron signal first passes through the region where the sub-electric field ΔE′₂ is located, and the sub-electric field ΔE′₂ enables the return electron signal to deflect for the first time along the direction of the sub-electric field ΔE′₂, where the deflection angle is γ. Since the energy of the return electron signal is less than the energy of the electron beam, the deflection angle γ of the return electron signal is greater than the deflection angle β of the electron beam. The return electron signal then passes through the region where the sub-electric field ΔE″₂ is located, and the sub-electric field ΔE″₂ enables the return electron signal to deflect for the second time along the direction of the sub-electric field ΔE″₂, where the deflection angle is γ. Under this condition, the moving direction of the return electron signal is parallel to the column axis m and is at the second distance d₂ from the column axis m of the electron microscope, where

$${d}_{2} = \frac{Δ {V}_{2} {h}_{2}^{2}}{4 {H}_{2} {U}_{3}} .$$

After passing through the second centering assembly 13, the return electron signal is collected by the detector.

It should be noted that, the field region in this example may be understood as an electric field region formed in a centering assembly.

In this example, in the path along which the electron beam moves to the test sample, the electron beam may be deflected along different directions by the first centering assembly 11 and the second centering assembly 13, so that the electron beam can act on the test sample along the emission direction of the electron beam, and the return electron signal detected by the detector 121 is effective signal. In the moving path of the return electron signal, the return electron signal may be deflected by the second centering assembly 13. Since the energy of the return electron signal is less than the energy of the electron beam, the deflection angles of the return electron signal and the electron beam in the second centering assembly 13 are different from each other, and the less the energy of the electron signal is, the greater the deflection angle is. In this way, the detector 121 may not block the moving path of the electron beam to the test sample while detecting the return electron signal, and the return electron signal may be detected without applying any voltage to the detector 121, thereby avoiding the effect of the high-voltage electric field in the moving path of the electron beam and improving the quality of the electron beam.

In order to better understand the embodiments of the present application, the moving processes of the return electron signals with different energies in the apparatus for detecting an electron shown in FIG. 2 of the present application will be described below with reference to FIG. 5.

The return electron signal may contain the electron signals with various energies, and the detector 121 may collect the electronic signals with different energies at the same time using different sub-receiving surfaces 41. The less the energy of the return electron signal is, the greater the distance from the column axis m is.

The voltage of the electron signal with the maximum energy of the return electron signals is marked as Uₘₐₓ, and the voltage difference between the electron signals with other energies and the electron signal with the maximum energy is marked as ΔU, then under a condition that the return electron signal is collected by the detector, the distance L from the column axis may be represented as

$$L = \frac{Δ {V}_{2} {h}_{2}^{2}}{4 {H}_{2}} ( \frac{1}{{U}_{max}} - \frac{1}{{U}_{max} + Δ U} ) .$$

In the example as shown in FIG. 5, the detector may include the plurality of sub-receiving surfaces 41. The sub-receiving surfaces 41 are configured to receive the return electron signals with different energies, respectively. For example, under a condition that it is desired to obtain the return electron signal with the voltage of Uₘ, the region corresponding to the return electron signal with the energy may be calculated, and the return electron signal received by the sub-receiving surface 41 where the region is located may be obtained by the microscope and imaged.

The return electron signals with different energies are received by the sub-receiving surfaces 41, so that the return electron signals with different energies are separately imaged by the electron microscope.

The energies of the return electron signals are different from each other, and the deflection angles of the return electron signals in the second centering assembly 13 are different from each other. After the return electron signal is deflected by the second centering assembly 13, under a condition that the return electron signal acts on the receiving surface of the detector, the distances of the return electron signals from the column axis m are different from each other. The greater the energy of the return electron signal is, the closer the return electron signal is to the column axis m is, so that the return electron signals with different energies may be collected by the plurality of sub-receiving surfaces 41 sequentially arranged along the radial direction of the column, and the return electron signals with different energies can be separately imaged by the electron microscope.

Based on the apparatus for detecting an electron, embodiments of the present application further provides a method for detecting an electron signal.

FIG. 6 is a schematic flowchart of a method for detecting an electron signal according to embodiments of the present application. As shown in FIG. 6, the method for detecting an electron signal according to the present application may include: S10, S11, S12, S13, and S14.

In S10, a first electrical signal is applied to the first centering assembly, and the electron beam is controlled to be deflected through the first centering assembly applied by the first electrical signal, so that the deflected electron beam deviates by the first distance from the column axis of the electron microscope.

In S11, a second electrical signal is applied to the second centering assembly, and the deflected electron beam is controlled to be re-deflected through the second centering assembly applied by the second electrical signal, so that the distance between the re-deflected electron beam and the column axis is less than the preset distance.

In S12, the electron beam deflected through the second centering assembly applied by the second electrical signal is converged by an objective lens, so that the converged electron beam acts on the test sample placed on the sample stage, and the test sample generates the return electron signal, where the energy of the return electron signal is less than the energy of the electron beam.

In S13, the return electron signal is controlled to be deflected through the second centering assembly applied by the second electrical signal, so that the deflected return electron signal deviates by the second distance from the column axis.

In S14, the deflected return electron signal is received by the detector assembly.

In this embodiment, the first electrical signal is applied to the first centering assembly, and the second electrical signal is applied to the second centering assembly, so that in the path along which the electron beam moves to the test sample, the electron beam may be deflected along different directions by the first centering assembly and the second centering assembly, the electron beam can act on the test sample along the emission direction of the electron beam, and the return electron signal detected by the detector is the effective signal. In the moving path of the return electron signal, the return electron signal may be deflected by the second centering assembly. Since the energy of the return electron signal is less than the energy of the electron beam, the deflection angles of the return electron signal and the electron beam in the second centering assembly are different from each other, and the less the energy of the electron signal is, the greater the deflection angle is. In this way, the detector may not block the moving path of the electron beam to the test sample while detecting the return electron signal, and the return electron signal may be collected without applying any voltage to the detector, thereby avoiding the effect of the high-voltage electric field in the moving path of the electron beam and improving the quality of the electron beam.

In some embodiments, optionally, step S14 in the method for detecting an electron signal shown in FIG. 6 of the present application may include: receiving, by each of the sub-receiving surfaces of the detector of the detector assembly, the return electron signal with the corresponding energy.

The energies of the return electron signals are different from each other, and the deflection angles of the return electron signals in the second centering assembly are different from each other. After the return electron signal is deflected by the second centering assembly, under a condition that the return electron signal acts on the receiving surface of the detector, the distances of the return electron signals from the column axis are different from each other. The greater the energy of the return electron signal is, the closer the return electron signal is to the column axis, so that the return electron signals with different energies may be collected by the plurality of sub-receiving surfaces sequentially arranged along the radial direction of the column, and the return electron signals with different energies can be separately imaged by the electron microscope.

Based on the apparatus for detecting an electron, embodiments of the present application further provide an electron microscope.

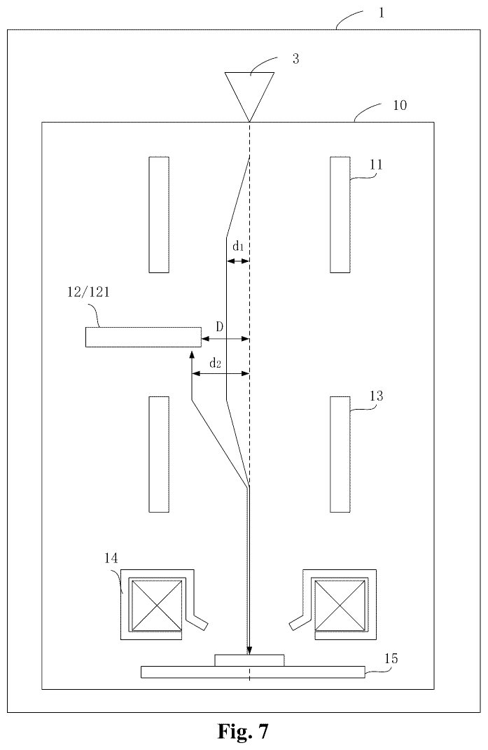

FIG. 7 is a schematic structural view of an electron microscope according to an embodiment of the present application. As shown in FIG. 7, the electron microscope 1 may include the electron beam emission source 3 and the apparatus 10 for detecting an electron shown in FIG. 2.

The electron microscope includes, but is not limited to, the transmission electron microscope, the scanning electron microscope, the scanning transmission electron microscope, and the like.

The applications of the electron microscope include, but are not limited to, detecting patterns on semiconductor silicon wafers and masks, measuring critical dimensions, and detecting defects such as open circuit and short circuit in electronic devices on integrated circuit boards.

In the electron microscope of the embodiment, in the path along which the electron beam moves to the test sample, the electron beam may be deflected along different directions by the first centering assembly and the second centering assembly in the apparatus for detecting an electron, so that the electron beam can act on the test sample along the emission direction of the electron beam, and the return electron signal detected by the detector in the apparatus for detecting an electron is the effective signal. In the moving path of the return electron beam, the return electron signal may be deflected by the second centering assembly in the apparatus for detecting an electron. Since the energy of the return electron signal is less than the energy of the electron beam, the deflection angles of the return electron signal and the electron beam in the second centering assembly are different from each other, and the less the energy of the electron signal is, the greater the deflection angle is. Therefore, the detector can avoid the electron beam and detect the return electron signal, and the return electron signal may be detected without applying any voltage to the detector, thereby avoiding the effect of the high-voltage electric field in the moving path of the electron beam, and improving the quality of the electron beam and the imaging quality of the electron signal.

The above are only specific implementations of the present application, those skilled in the art may clearly understand that the specific operating processes of the above systems, modules and units may be referred to the corresponding processes in the embodiments of the foregoing method, which is not repeated here for the convenience and brevity of the description. It should be understood that the protection scope of the present application is not limited to this, and any person skilled in the art can easily think of various equivalent modifications or replacements within the technical scope disclosed in the present application, and these modifications or replacements should all be covered within the scope of protection of the present application.

What is claimed is:

1. An apparatus for detecting an electron, applied to an electron microscope, wherein the apparatus for detecting an electron comprises a first centering assembly, a detector assembly, a second centering assembly, an objective lens, and a sample stage for placing a test sample;
the first centering assembly is configured to control an electron beam to be deflected, so that the deflected electron beam deviates by a first distance from a column axis of the electron microscope;
the second centering assembly is configured to control the deflected electron beam to be re-deflected, so that a distance between the re-deflected electron beam and the column axis is less than a preset distance;
the objective lens is configured to converge the electron beam deflected by the second centering assembly, so that the converged electron beam acts on the test sample, and the test sample generates a return electron signal under an action of the electron beam, wherein an energy of the return electron signal is less than an energy of the electron beam;
the second centering assembly is further configured to control the return electron signal to be deflected, so that the deflected return electron signal deviates by a second distance from the column axis; and
the detector assembly deviates from the column axis to avoid the electron beam passing through the first centering assembly and is configured to receive the deflected return electron signal.

2. The apparatus according to claim 1, wherein the first centering assembly, the detector assembly, the second centering assembly, the objective lens, and the sample stage are sequentially provided along the column axis;
the first centering assembly comprises a first centering component and a second centering component that are sequentially provided along a direction of the column axis;
the first centering component is configured to control the electron beam to be deflected by a first preset angle along a direction away from the column axis; and
the second centering component is configured to control the electron beam deflected by the first preset angle to be re-deflected along a direction approaching the column axis, so that the re-deflected electron beam deviates by the first distance from the column axis of the electron microscope.

3. The apparatus according to claim 2, wherein the second centering assembly comprises a third centering component and a fourth centering component that are sequentially provided along the direction of the column axis;
the third centering component is configured to control the electron beam to be deflected by a second preset angle along the direction approaching the column axis; and
the fourth centering component is configured to control the electron beam deflected by the second preset angle to be re-deflected along the direction away from the column axis, so that a distance between the re-deflected electron beam and the column axis is less than the preset distance.

4. The apparatus according to claim 3, wherein each of the first centering component, the second centering component, the third centering component, and the fourth centering component comprises:
a first conductive plate and a second conductive plate.

5. The apparatus according to claim 3, wherein each of the first centering component, the second centering component, the third centering component, and the fourth centering component comprises a conductive coil.

6. The apparatus according to claim 1, wherein the detector assembly comprises at least one detector comprising a receiving surface for receiving the return electron signal.

7. The apparatus according to claim 6, wherein the receiving surface comprises a plurality of sub-receiving surfaces sequentially arranged along a radial direction of a column, and each of the sub-receiving surfaces is configured to receive the return electron signal with a corresponding energy.

8. A method for detecting an electron signal, applied to an apparatus for detecting an electron, applied to an electron microscope, wherein the apparatus for detecting an electron comprises a first centering assembly, a detector assembly, a second centering assembly, an objective lens, and a sample stage for placing a test sample; the first centering assembly is configured to control an electron beam to be deflected, so that the deflected electron beam deviates by a first distance from a column axis of the electron microscope; the second centering assembly is configured to control the deflected electron beam to be re-deflected, so that a distance between the re-deflected electron beam and the column axis is less than a preset distance; the objective lens is configured to converge the electron beam deflected by the second centering assembly, so that the converged electron beam acts on the test sample, and the test sample generates a return electron signal under an action of the electron beam, wherein an energy of the return electron signal is less than an energy of the electron beam; the second centering assembly is further configured to control the return electron signal to be deflected, so that the deflected return electron signal deviates by a second distance from the column axis;
and the detector assembly deviates from the column axis to avoid the electron beam passing through the first centering assembly and is configured to receive the deflected return electron signal, wherein the method for detecting the electron signal comprises:
applying a first electrical signal to the first centering assembly, and controlling, through the first centering assembly applied by the first electrical signal, the electron beam to be deflected, so that the deflected electron beam deviates by the first distance from the column axis of the electron microscope;
applying a second electrical signal to the second centering assembly, and controlling, through the second centering assembly applied by the second electrical signal, the deflected electron beam to be re-deflected, so that the distance between the re-deflected electron beam and the column axis is less than the preset distance;
converging, by an objective lens, the electron beam deflected by the second centering assembly to which the second electrical signal is applied, so that the converged electron beam acts on the test sample placed on the sample stage, and the test sample generates the return electron signal, where the energy of the return electron signal is less than the energy of the electron beam;
controlling, by the second centering assembly to which the second electrical signal is applied, the return electron signal to be deflected, so that the deflected return electron signal deviates by the second distance from the column axis; and
receiving the deflected return electron signal by the detector assembly.

9. The method according to claim 8, wherein the detector assembly comprises at least one detector comprising a receiving surface, and the receiving surface comprises the plurality of sub-receiving surfaces sequentially arranged along a radial direction of a column; and
the receiving the deflected return electron signal by the detector assembly comprises:
receiving, by each of the sub-receiving surfaces of the detector of the detector assembly, the return electron signal with a corresponding energy.

10. An electron microscope comprising an apparatus for detecting an electron, applied to an electron microscope, wherein the apparatus for detecting an electron comprises a first centering assembly, a detector assembly, a second centering assembly, an objective lens, and a sample stage for placing a test sample; the first centering assembly is configured to control an electron beam to be deflected, so that the deflected electron beam deviates by a first distance from a column axis of the electron microscope; the second centering assembly is configured to control the deflected electron beam to be re-deflected, so that a distance between the re-deflected electron beam and the column axis is less than a preset distance; the objective lens is configured to converge the electron beam deflected by the second centering assembly, so that the converged electron beam acts on the test sample, and the test sample generates a return electron signal under an action of the electron beam, wherein an energy of the return electron signal is less than an energy of the electron beam; the second centering assembly is further configured to control the return electron signal to be deflected, so that the deflected return electron signal deviates by a second distance from the column axis; and the detector assembly deviates from the column axis to avoid the electron beam passing through the first centering assembly and is configured to receive the deflected return electron signal.
